(19) United States
(12) Patent Application Publication
(10) Pub. No.: US 2024/0145415 A1
(43) Pub. Date: May 2, 2024

(54) ELECTRONIC DEVICE AND ELECTRONIC APPARATUS

(71) Applicant: PanelSemi Corporation, New Taipei City (TW)

(72) Inventor: HSIEN-TE CHEN, Taipei City (TW)

(21) Appl. No.: 18/496,225

(22) Filed: Oct. 27, 2023

Related U.S. Application Data
(60) Provisional application No. 63/436,264, filed on Dec. 30, 2022.
(60) Provisional application No. 63/420,246, filed on Oct. 28, 2022.

(51) Int. Cl. H01L 23/66; H01L 23/498; H01Q 1/22; H01Q 9/04

(52) U.S. Cl. CPC H01L 23/66; H01L 23/49805; H01L 23/49827; H01Q 1/2283; H01Q 9/0407; H01L 24/16; H01L 2223/6627; H01L 2223/6661; H01L 2223/6677

(57) ABSTRACT

An electronic device and an electronic apparatus having the same are provided. The electronic device comprises a substrate defining a first face and a second face opposite to each other, a thin film layer formed on the first face of the substrate, one or more passive elements arranged on the thin film layer, and one or more semiconductor chips are disposed on the first face of the substrate and electrically connecting to the thin film layer. One or ones of the semiconductor chips define an operating frequency not less than 1 GHz.

### CROSS REFERENCE TO RELATED APPLICATIONS

This Non-provisional application claims priority under 35 U.S.C. § 119(a) on Patent Application No(s). 63/420,246 filed in United States of America on Oct. 28, 2022, and Patent Application No(s). 63/436,264 filed in United States of America on Dec. 30, 2022, the entire contents of which are hereby incorporated by reference.

### BACKGROUND

### Technology Field

The disclosure relates to an electronic device and an electronic apparatus comprising the electronic device.

### Description of Related Art

In the communication field, a signal source and a signal receiving end are connected with traces having the same resistance to achieve impedance matching. However, it is not easy to achieve impedance matching on a PCB with complex components.

### SUMMARY

One or more exemplary embodiments of this disclosure are to provide an electronic apparatus and an electronic device applicable to the electronic device.

An electronic device includes a substrate, a thin film layer, one or more passive elements, and one or more semiconductor chips. The substrate defines a first face and a second face opposite to each other. The thin film layer is formed on the first face of the substrate. The one or ones of the passive element are arranged on the first face of the substrate or on the thin film layer and electrically connecting to the thin film layer. The one or ones of the semiconductor chips are disposed on the first face of the substrate or on the thin film layer, and electrically connecting the thin film layer. One or ones of the semiconductor chips define an operating frequency as being no less than 1 GHz.

In one embodiment, one or ones of the passive element(s) is integrally made of the thin film layer.

In one embodiment, the passive element includes at least one of a resistor, an inductor, a capacitor, a coupler, a microstrip, or an impedance matching unit.

In one embodiment, one or ones of the passive element are individually disposed thereon.

In one embodiment, the operating frequency of one or ones of the semiconductor chip(s) is no less than 10 GHz.

In one embodiment, the substrate defines a dissipation factor is no greater than 0.01.

In one embodiment, the substrate defines a dissipation factor no greater than 0.008.

In one embodiment, the substrate defines a dissipation factor no less than 0.0004.

In one embodiment, the substrate is an insulating substrate.

In one embodiment, the substrate includes glass materials.

In one embodiment, the substrate is a flexible substrate.

In one embodiment, the thin film layer includes a layer of thin metallic foil.

In one embodiment, the semiconductor chip(s) is made of a material(s) with a band gap no less than 1 electron volt.

In one embodiment, the semiconductor chip(s) is made of a material(s) with a band gap not less than 1.4 electron volt.

In one embodiment, the semiconductor chip(s) is an epitaxial structure(s) lift-off from an original wafer.

In one embodiment, the original wafer is made of materials of gallium nitride (GaN), silicon carbide (SiC), sapphire, gallium arsenide (GaAs), silicon (Si), or indium phosphide (InP).

In one embodiment, the semiconductor chip(s) is compound semiconductor(s) applied to radio frequency (RF) range.

In one embodiment, the thin film layer further defines a feeding line.

In one embodiment, the electronic device further includes a first conductive layer formed on the second face of the substrate.

Ine one embodiment, the first conductive layer is a grounding layer or a common layer.

Ine one embodiment, the electronic device further includes one or more first conductors for electrically connecting the first conductive layer with the thin film layer.

In one embodiment, the electronic device further includes a second conductive layer formed on the first face of the substrate, and the second conductive layer is arranged between the substrate and the semiconductor chip(s).

In one embodiment, the electronic device further includes a second conductive layer formed on the semiconductor chip(s), and the semiconductor chip(s) is arranged between the substrate and the second conductive layer.

In one embodiment, the first conductive layer fully covers one or ones of the semiconductor chips in a projection direction perpendicular to the substrate.

In one embodiment, one or more assisting conductors are provided to the electronic device, and the assisting conductor(s) is electrically connected to the first conduction layer.

In one embodiment, the semiconductor chip(s) include(s) transistor(s), diode(s), or varactor(s), or any combination thereof.

In one embodiment, a light shielding member is further provided to the electronic device, and the light shielding member covers one or more faces of the substrate.

An electronic apparatus is further disclosed. The electronic apparatus includes a board defining a third conductive layer, one or ones of the electronic device abovementioned, and a plural of second conductors electrically connecting the board and the electronic device.

In one embodiment, the second conductors are arranged between the board and the electronic device(s), the second conductor(s) defines a thickness greater than a thickness of the semiconductor chip(s).

In one embodiment, the second conductor(s) is arranged between the board and the electronic device(s), the second conductor(s) defines a thickness less than a thickness of the semiconductor chip(s), while the board defines a recess for accommodating the semiconductor chips.

In one embodiment, the second conductor(s) is arranged between a third conductive layer of the board and the thin film layer of the electronic device.

In one embodiment, the second conductor(s) is arranged between the board and the semiconductor chip(s) of the electronic device.

In one embodiment, the second conductors(s) connects the first conductor(s) through the thin film layer.

In one embodiment, further including a third conductive layer formed on the board, and the third conductive layer fully covers one or ones of the semiconductor chips in a projection direction perpendicular to the substrate.

In one embodiment, the second conductor(s) electrically connects to the second conductive layer with the thin film layer of the electronic device(s).

In one embodiment, second conductor(s) at least overlapping one of the first conductor(s) respectively in a projection direction perpendicular to the substrate.

In one embodiment, one or more antenna units are provided and arranged on the board; the antenna unit(s) and the electronic device(s) are arranged at opposite sides of the board.

In one embodiment, the antenna unit(s) includes one or more patch antennas.

In one embodiment, one or more light shielding members are further provided for covering the electronic device(s) and jointing the board.

### BRIEF DESCRIPTION OF THE DRAWINGS

The present invention will become more fully understood from the subsequent detailed description and accompanying drawings, which are given by way of illustration only, and thus are not limitative of the present invention, and wherein:

FIG. 1 is a side view showing a schematic diagram of an electronic device according to the present invention;

FIG. 2A and FIG. 2B are side views showing the electronic device with first conductive layer according to the present invention;

FIG. 3A and FIG. 3B are side views showing the electronic device with a second conductive layer according to the present invention;

FIG. 4 are side views showing different types of the first conductor applicable to the electronic device;

FIG. 5A and FIG. 5B are side views showing types of the semiconductor chips;

FIG. 6 a side view showing a schematic diagram of an electronic apparatus comprising the electronic device according to the present invention;

FIG. 7A to FIG. 7C are side views showing different embodiments of the electronic apparatus comprising the electronic device according to the present invention;

FIG. 8A to FIG. 8C are side views showing different embodiments of electrically connection of the semiconductor chips according to the present invention;

FIG. 9 is a side view showing the electronic device with passive elements according to the present invention; and

FIG. 10A and FIG. 10B are side views showing the electronic device with an antenna unit according to the present invention.

### DETAILED DESCRIPTION OF THE DISCLOSURE

The disclosure will become more fully understood from the detailed description and accompanying drawings, which are given for illustration only, and thus are not limitative of the present disclosure.

The electronic device of the present invention includes in a substrate, a thin film layer, one or more passive elements, and one or more semiconductor chips.

The substrate defines a first face and a second face opposite to each other. The substrate defines a dissipation factor no greater than 0.01 or/and no less than 0.0004. The dissipation factor of the substrate can be ranged between 0.0004 and 0.01, for example, the dissipation factor of the substrate can be 0.0077, 0.008, 0.003, 0.019, etc.

The substrate can be an insulating substrate such as glass substrate or a substrate includes glass materials, but not limited. In another embodiment, the substrate can be a flexible substrate.

The thin film layer is formed on the first face of the substrate, in particularly, the thin film layer is formed by a thin film process. The thin film process could develop the thin film layer of materials ranging from fractions of a nanometer (monolayer) to several micrometers in thickness formed on the substrate in an integral manner, in which the thin film layer may be formed by one or more layers. The thin film layer also could made by a thin metallic foil, such as copper foil, silver foil or the like. The thin metallic foil is pressured and expanded onto the substrate. The thin film layer can further define one or more feeding lines therein in an optional manner.

The passive element(s), arranged on the substrate or the thin film layer, is electrically connected to the thin film layer. In one embodiment, the passive element is individually disposed on the thin film layer or the substrate, or in another embodiment, the passive element integrally made of the thin film layer. The passive element includes at least one of a resistor, an inductor, a capacitor, a coupler, a microstrip, or an impedance matching unit. The passive element per se may be an integrated passive device, so called Integrated passive devices (IPDs) and integrated formed in advance, and also is individually disposed upon the electronic device.

To be noted, the passive element(s) can be applied on the substrate or the thin film layer in a direct or indirect manner, and it is easy to understand that the passive element applied on the thin film layer is one kind of an indirect connection manner to the substrate. To be noted, the passive element(s) applied on the substrate also can be integrally formed of thin film layer.

Further, the feeding line defined of the thin film layer works with the passive element, ex. the resistor, the inductor, or the capacitor, arranged thereon.

The one or ones of the semiconductor chips are disposed on the first face of the substrate or on the thin film layer, and electrically connecting the thin film layer. One or ones of the semiconductor chips define an operating frequency as being no less than 1 GHz.

Material(s) of the semiconductor chip(s) defines a band gap no less than 1 electron volt (eV). In one embodiment, the band gap is no less than 1.1 eV, in which the material(s) of the semiconductor chip(s) is selected as Silicon. In another embodiment, the band gap is no less than 1.4 eV, in which the material(s) of the semiconductor chip(s) is selected as III-V compound.

The semiconductor chips can be individually arranged on the first face or/and second face of the substrate, and the semiconductor chips may electrically connect with each other through the thin film layer.

The semiconductor chip(s) can be a compound semiconductor applied to radio frequency (RF) range. The semiconductor chip(s) includes a transistor, a diode, a varactor, or any combination thereof.

Further, one or more resistors, one or more inductors, or one or more capacitors can be provided and formed within the semiconductor chip(s) in an optional manner.

One or more thin film transistors can be further provided and arranged on the substrate. The thin film transistor electrically connects the thin film layer and the semiconductor chip(s). In one embodiment, the thin film layer and the thin film transistor(s) are formed on the substrate together by a thin film process.

The electronic device in this invention can further include a diode, ex. light-emitting diode (LED) unit. The LEDs can be arranged on the substrate or separately from the substrate. In one embodiment, one or more LED units are arranged on the substrate, and each of the LED units includes one or more LEDs. In another embodiment, the LED unit(s) is disposed on another board or film and connect to the substrate, in which the connection manner of the LED unit(s) is not restrained. For example, one or ones of the LED units can be formed with the substrate as a whole package, or a tile. In another example, one or ones of the LED units are formed in an array on the substrate. In one embodiment, one or ones of the semiconductor chips per se are diodes.

The present disclosure will be apparent from the following detailed description, which proceeds with reference to the accompanying drawings, wherein the same references relate to the same elements.

### Embodiment 1

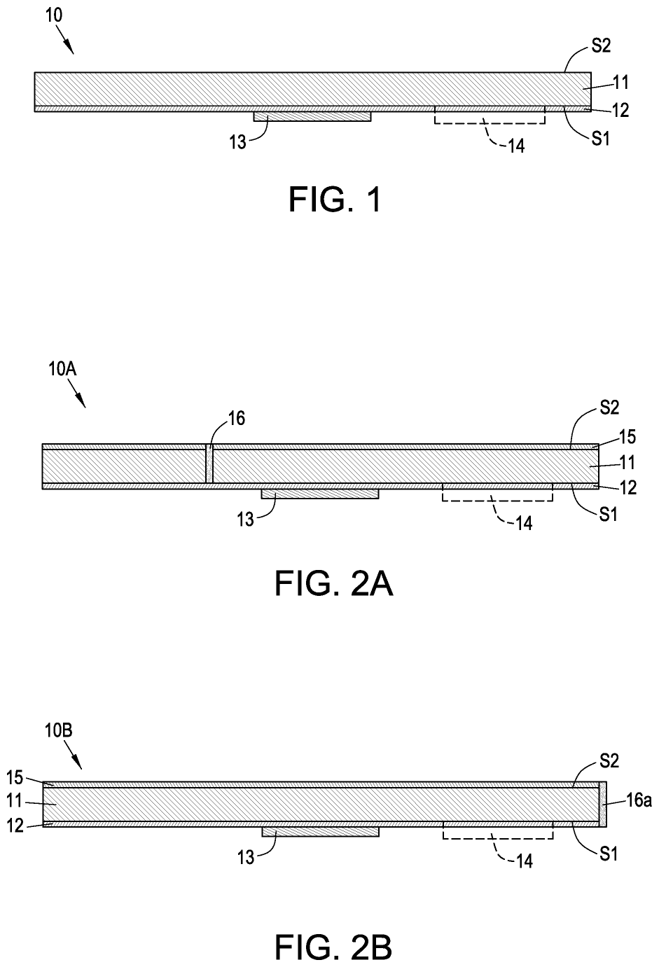

Referring to FIG. 1, an electronic device 10 is disclosed. The electronic device 10 includes a substrate 11, a thin film layer 12, one or more semiconductor chips 13, and one or more passive elements 14. The substrate 11 defines a first face S1 and a second face S2 opposite to each other. The thin film layer 12 is formed on the first face S1 of the substrate 11. One or ones of the semiconductor chips 13 are disposed on the first face S1 of the substrate 11 and electrically connecting the thin film layer 12. One or ones of the semiconductor chips 13 define an operating frequency which is no less than 1 GHz, such as 2.4 GHz or 5 GHz. In some embodiments, the operating frequency of the semiconductor chip(s) is no less than 10 GHz. The passive element(s) 14 is arranged on the thin film layer 12 or integrated on the thin film layer 12. In one embodiment, the passive element 14 includes at least one of a resistor, an inductor, a capacitor, a coupler, a microstrip, or an impedance matching unit. In another embodiment, the passive element 14 includes an integrated passive device and disposed on the thin film layer 12.

The passive element 14 can also be disposed on the substrate 11 and electrically connecting the thin film layer 12 in this embodiment. Furthermore, the passive element 14, ex. a resistor, an inductor, a capacitor, a coupler, a microstrip, or an impedance matching unit, or any combination thereof, is formed integrally with the thin film layer 12. In one embodiment, the passive element 14 is an individual and further transferred on the substrate 11 and electrically connecting the thin film layer 12. In another embodiment, the passive element 14 may be integrally made of the thin film layer 12 on the substrate 11. In another embodiment, the passive element 14 may only be part of a trace of the thin film layer 12, such as a coupler, a microstrip, or an impedance matching unit. The passive element 14 per se may be an integrated passive device, so called Integrated passive devices (IPDs). To be noted, the passive element 14 can be a single component or a combination includes one or more embodiments mentioned above and equivalents thereof.

In this embodiment, the substrate 11 is an insulation substrate. The substrate 11 can also be a flexible substrate. The substrate 11 could be a single board, a multi-layer board with one or more inner conductive layers, or a combination board with various materials of boards and one or more inner conductive layers. In this embodiment, the substrate 11 is the single board.

### Embodiment 2

Referring to FIG. 2A, an electronic device 10A is disclosed. The electronic device 10A has a similar structure to the electronic device 10 in FIG. 1, but the electronic device 10A further includes a first conductive layer 15. The first conductive layer 15 is formed on the second face S2 of the substrate 11, and one or more first conductors 16 are provided for electrically connecting the first conductive layer 15 with the thin film layer 12. In this embodiment, the first conductive layer 15 is functioned as a grounding layer or common layer. The first conductors 16 would be arranged either in within or by the substrate 11. In this embodiment, the first conductor(s) 16 is arranged within the first substrate 11.

Referring to FIG. 2B, the first conductor 16 can be also arranged at an outline of the substrate 11 for electrically connecting the first conductive layer 15 with the thin film layer 12.

### Embodiment 3

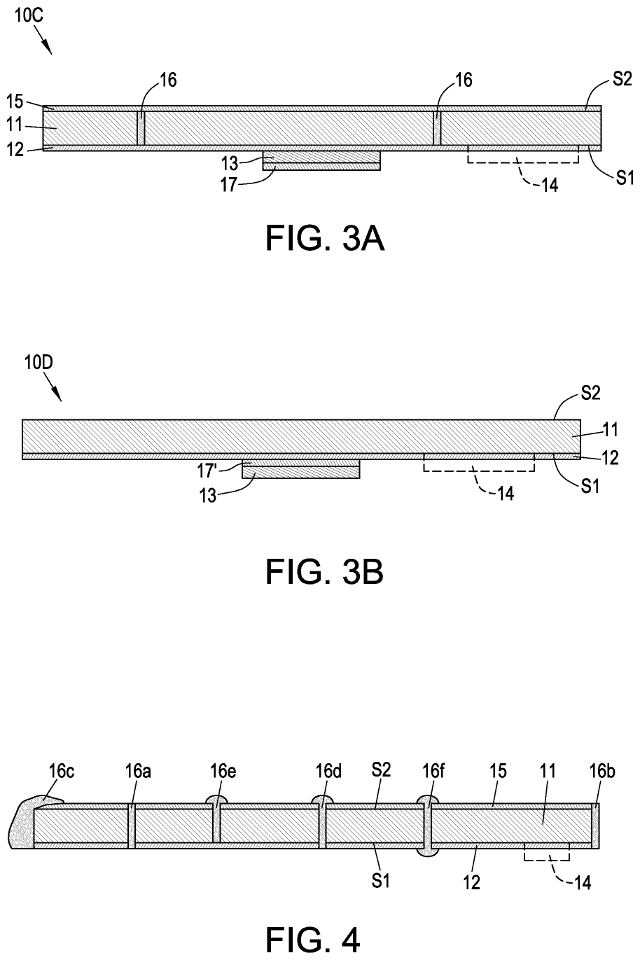

FIG. 3A shows an electronic device 10C having the first conductive layer 15 and a second conductive layer 17. The second conductive layer 17 is formed on the semiconductor chip(s) 13 in which the semiconductor chip(s) 13 is arranged between the substrate 11 (or the thin film layer 12) and the second conductive layer 17.

FIG. 3B is another embodiment of the present invention. The electronic device 10D in FIG. 3B is provided with the second conductive layer 17′ on the first face S1 of the substrate 11 (or on the thin film layer 12). The second conductive layer 17′ is arranged between the substrate 11 (or the thin film layer 12) and the semiconductor chip(s) 13.

The abovementioned first conductive layer 15 and the second conductive layer 17/17′ could fully cover the semiconductor chip(s) 13 in a projection direction perpendicular to the substrate 11, and either one or both of the first conductive layer 15 and the second conductive layer 17/17′ are a grounding layer or a common layer.

### Embodiment 4

In this embodiment, different types of the first conductor 16 is disclosed as exemplary. However, this embodiment does not intend to limit the types of the first conductor 16. Referring to FIG. 4, the first conductor 16a can be disposed in a via V within the substrate 11, and two ends of the first conductor 16a are respectively covered and sealed by the thin film layer 12 and the first conductive layer 15, or covered and sealed by conductive pads electrically connected to the thin film layer 12 and the first conductive layer 15.

In other embodiments, one or two ends of the first conductor 16 are not covered or sealed. For example, one end of the first conductor 16d and the first conductor 16f are at least slightly protruded from the outer surface of the first conductive layer 15. In another embodiment, both ends of the first conductor 16f are at least slightly protruded from the outer surface of the first conductive layer 15 and the outer surface of the thin film layer 12.

The first conductor can also be arranged at sides of the substrate 11 and electrically connecting the thin film layer 12 to the first conductive layer 15 as the first conductor 16b and the first conductor 16c in FIG. 4.

The first conductors are shown in FIG. 4. They can be implemented by lasering, printing, pasting, or approaches the like.

### Embodiment 5

In this invention, at least one circuitry is formed on the substrate 11, and the circuitry includes one or more circuit units. The semiconductor chip(s) 13 exists in each one of the circuit units.

One or ones of the semiconductor chips 13 are individual(s) arranged on either the first face S1 or the second face S2 of the substrate 11, and the semiconductor chips 13 may electrically connect with each other through the thin film layer 12.

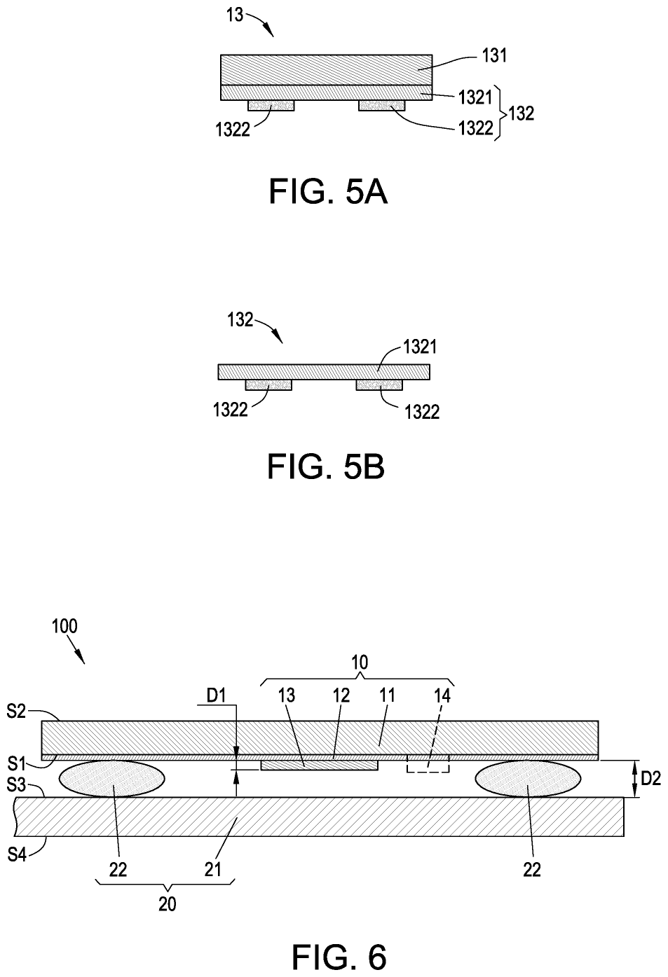

Referring to FIG. 5A, the semiconductor chip(s) 13 includes an original wafer 131 and an epitaxial structure 132 formed on the original wafer 131. The original wafer 131 is made of materials of gallium nitride (GaN), silicon carbide (SiC), sapphire, gallium arsenide (GaAs), silicon (Si), or indium phosphide (InP).

Alternatively, the semiconductor chip(s) 13, referred in FIG. 5B, is merely epitaxial structure(s) 132 which is lift off from the original wafer 131. The epitaxial structure(s) 132 mentioned in FIG. 5B includes a functional base 1321 and one or more pads 1322 electrically connecting the functional base 1321. The pad(s) 1322 can be arranged facing to the substrate 11/the thin film layer 12, or the pad(s) 1322 can be arranged away from the substrate 11/the thin film layer 12. The functional base 1321 may further define a transmission line (not shown in the FIGs) and one or more functional units (not shown in the FIGs) electrically connecting to the transmission line. The pad(s) 1322 can link to a respective functional unit(s) and connect thereto by the transmission line or not.

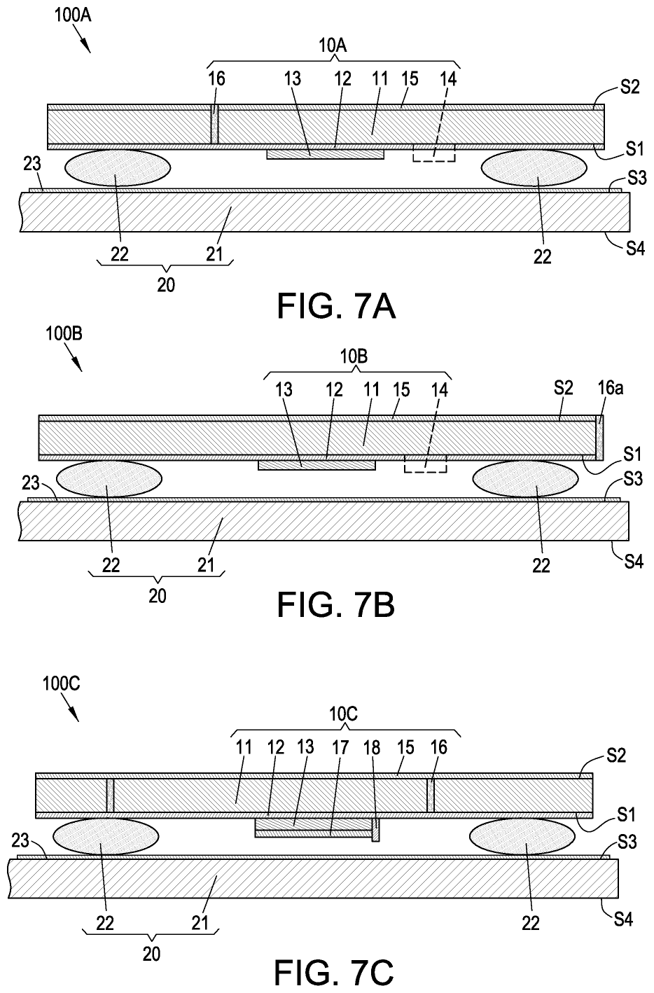

One or ones the pads 1322 of one or ones of the semiconductor chips 13 may electrically connects to the third conductive layer on the board 20, in which the third conductive layer may be numbered as 23 and illustrated in FIGS. 7A-7C, 8A-8C, 9 and 10B, through the second conductors 22, in which the third conductive layer has transmission line function.

### Embodiment 6

Please refer to FIG. 6, one or ones of the electronic device 10 abovementioned can be assemble with a bord unit 20 to form an electronic apparatus 100. The board unit 20 includes a board 21 and a plural of second conductors 22. The board 21 define a third conductive layer (not shown in FIG. 6) on a third surface S3 or a four surface S4 of the board 21, and the second conductor(s) 22 electrically connects the third conductive layer of the board unit 20 and the electronic device(s) 10. The second conductors 22 could be implemented by any manner, such as lasering, soldering, pasting, jetting or equivalent approaches the like, and the shape of the second conductors 22 illustrated thereof is not limited to round shape. In FIG. 6, the second conductors 22 are arranged between the board 21 and the electronic device(s) 10. A thickness D2 of the second conductors 22 in FIGS. 6, and D2 is greater than a thickness D1 of the semiconductor chip(s) 13, but not limited.

In one embodiment, the second conductors 22 at least overlapping one or ones of the first conductors 16 respectively in a projection direction perpendicular to the substrate 11.

Materials, layers and types of the board 21 are not limited, and the way how the electronic device 10 and the board 21 arrange is not limited as well. In this case, the electronic device 10 and the board 21 may be arranged in a one-on-one manner, plural-on-one, or one-on-plural manner.

### Embodiment 7

Referring to FIG. 7A, the electronic apparatus 100A includes a first conductive layer 15 on the second face S2 of the electronic device 10A and a third conductive layer 23 on the third surface S3 of the board 21. The first conductive layer 15 can be electrically connected to the third conductive layer 23 of by any combination of the first conductor(s) 16, the thin film layer 12, and the second conductor 22. For example, the first conductive layer 15 is electrically connected to the third conductive layer 23 by the first conductor(s) 16, the thin film layer 12, and the second conductor 22 in FIG. 7A.

The electronic apparatus 100B in FIG. 7B has a similar structure to the electronic apparatus 100A in FIG. 7A. However, the first conductor(s) 16 in FIG. 7A is arranged in the substrate 11, and the first conductor(s) 16a is arranged at a peripheral of the substrate 11.

In FIG. 7C, the first conductive layer 15 of the electronic apparatus 100C is electrically connected to the third conductive layer 23 of the board 21 via the first conductors 16, the thin film layer 12, and the second conductors 22. A second conductive layer 17 is further provided to the electronic apparatus 100C. The second conductive layer 17 is arranged on the semiconductor chip 13 of the electronic device 10C, and an assisting conductor 18 is provided for electrically connecting the second conductive layer 17 and the thin film layer 12. The assisting conductor 18 can be implemented in any approach, such as wiring or other approach having the same function. The semiconductor chip 13 can electrically connects to the thin film layer 12 by pads facing to the substrate 11.

The semiconductor chip 13 can be a chip with full functions, or a deducted functional part arranged on the substrate 11. The semiconductor chip 13 can be arranged on the board 21 of the board unit 20 either. When the semiconductor chip 13 is a deducted functional part arranged on the substrate 11 or the board 21, the assisting conductors 18 or the second conductors 22 shall complete the function of the deducted functional part.

In one embodiment, one or ones of the second conductors 22 at least overlapping one or ones of the first conductors 16 respectively in a projection direction perpendicular to the substrate 11. In addition, one or ones of the second conductors 22 electrically connects one or ones of the first conductors 16 through the thin film layer 12.

### Embodiment 8

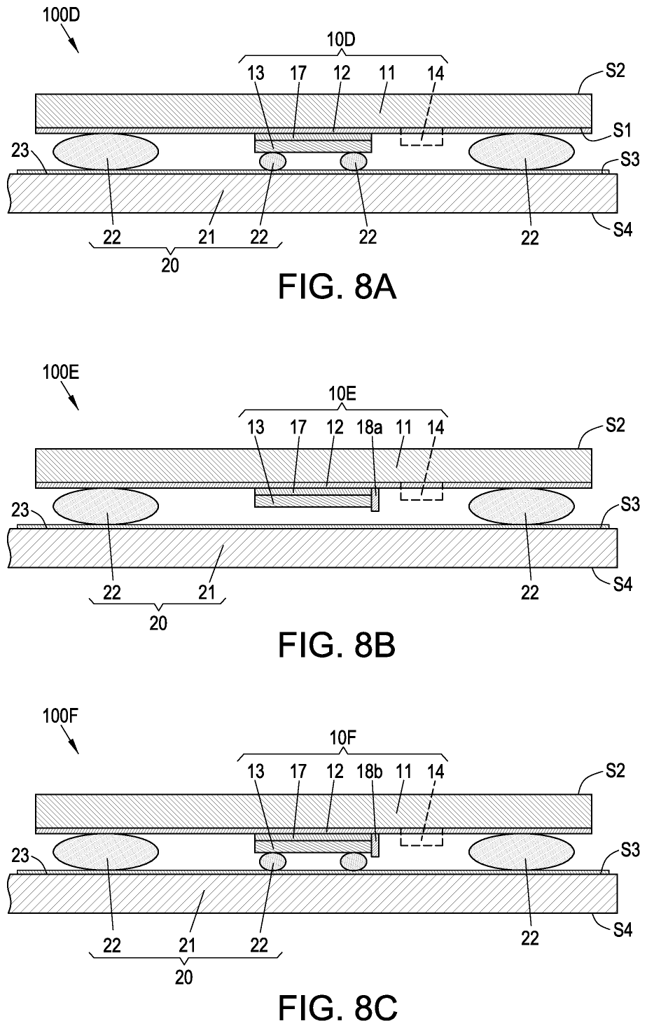

Referring to FIG. 8A a second conductive layer 17 is provided to the electronic apparatus 100D and is arranged between the semiconductor chip 13 and the thin film layer 12, and the second conductive layer 17 is electrically connected to the third conductive layer 23 of the board 21 by the thin film layer 12 and the second conductor 22, or any combination thereof.

In FIG. 8B, the second conductive layer 17 is arranged between the semiconductor chip 13 and the thin film layer 12 of the electronic device 10E, and the semiconductor chip 13 is electrically connected to the third conductive layer 23 on the board 21 by an assisting conductor 18a, the thin film layer 12 and the second conductor 22.

In this embodiment, the pad of the semiconductor chip(s) 13 is away from the substrate 11 and electrically connects the thin film layer 12 through an assisting conductor 18a, such as by wiring, for comprehension but not limit.

In FIG. 8C, the second conductive layer 17 is arranged between the semiconductor chip 13 and the thin film layer 12 of the electronic device 10F. In this embodiment, the transmission line of the semiconductor chip 13 is arranged on either the substrate 11 or the board 21, and the transmission line is electrically connected to the thin film layer 12 or the third conductive layer 23 of the board 21 in an integrity manner or not. One pad of the semiconductor chip 13 may electrically connect to the thin film layer 12 with the transmission line by the assisting conductor 18b, and another pad of the semiconductor chip 13 may electrically connect to the third conductive layer 23 of the board 21 by the second conductors 22.

### Embodiment 9

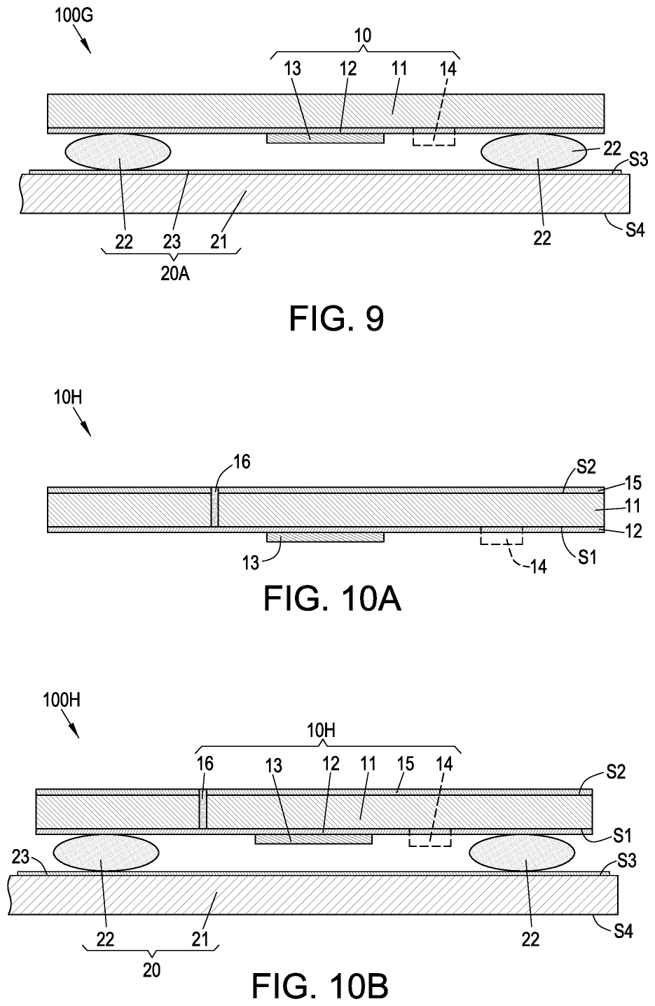

Please refer to FIG. 9, an electronic apparatus 100G includes the electronic device 10G and the board unit 20A is disclosed. The electronic apparatus 100G includes a third conductive layer 23 disposed on the board 21 facing the electronic device(s) 10G. The third conductive layer 23 fully covers a projection of one or ones of the semiconductor chips 13 in a direction perpendicular to the substrate 11 of the electronic device 10G.

Each of the abovementioned electronic devices 10A-10G can be further provide with one or more antenna units (not shown). The antenna unit(s) is arranged on the fourth surface S4 of the board 21, which means the substrate 11 and the antenna unit are at opposite sides of the board 21. To be noted, each of the antenna unit is described as a patch antenna, and the patch antennas are individual from each other. The patch antennas and one or ones of the electronic device 10-10G constitutes a plural of antenna elements together. The antenna unit and the corresponded electronic device 10-10G may arranged in one-on-one manner, plural-on-one manner, or one-on-plural manner.

### Embodiment 10

Please refer to FIG. 10A, the electronic device 10H comprises the first conductive layer 15 on the second face S2 of the substrate 11, in which the first conduct layer 15 itself is an antenna unit layer in this embodiment. The antenna unit layer includes one or more patch antennas formed individually from each other. The patch antenna(s) can be driven by the semiconductor chip(s) 13 by the electromagnetic induction with the thin film layer 12. The patch antenna(s) can also be driven by the semiconductor chip(s) 13 by one or more first conductors 16 electrically connecting the first conductive layer 15 and the thin film layer 12. The patch antennas of the patch antenna layer (the first conductive layer 15) in this embodiment are arranged consecutively but intermittently. In this embodiment, the first conductor(s) 16 is arranged within the substrate 11, and works as a feeding line(s) corresponding to the patch antenna(s). In another embodiment, the first conductor(s) 16 may be arranged aside by the substrate 11.

Referring to FIG. 10B, an electronic apparatus 100H is disclosed, in which the electronic device 10H together with the board unit 20 constitute the electronic apparatus 100H, and the board unit 20 includes the board 21 and the second conductor(s) 22.

### Embodiment 11

In this embodiment, the substrate of the electronic device includes plural faces, ex. more than six surfaces, and a light shielding member is provided to cover at least one or more faces of the substrate. Optionally, the light shielding member(s) covers the electronic device(s) and joins the board of the board unit. In addition, the light shielding member can only cover the substrate of the electronic device or cover the whole electronic device. The light shielding member may be implemented onto the electronic device in a one-on-one manner or in a one-on-plural manner. The light shielding member is made of light absorption materials, such as dark or black particles, dark or black films or dark or black layers.

Accordingly, the present invention comprises a substrate defining a first face and a second face opposite to each other, a thin film layer formed on the first face of the substrate, one or more passive elements arranged on the thin film layer, and one or more semiconductor chips are disposed on the first face of the substrate and electrically connecting to the thin film layer. One or ones of the semiconductor chips define an operating frequency not less than 1 GHz. The passive element includes at least one of a resistor, an inductor, a capacitor, a coupler, a microstrip, or an impedance matching unit. However, the passive element can also be an integrated passive device. Therefore, the present invention is easy to achieve impedance matching since the passive element is formed on the thin film layer.

What is claimed is:

1. An electronic device, comprising:
a substrate defining a first face and a second face opposite to each other;
a thin film layer formed on the first face of the substrate;
one or more passive elements arranged on the first face of the substrate or the thin film layer and electrically connecting to the thin film layer; and
one or more semiconductor chips are disposed on the first face of the substrate or on the thin film layer, and electrically connecting to the thin film layer; wherein one or ones of the semiconductor chips define an operating frequency not less than 1 GHz.

2. The electronic device as claimed in claim 1, wherein one or ones of the passive elements are integrally made of the thin film layer.

3. The electronic device as claimed in claim 1, wherein the passive element includes at least one of a resistor, an inductor, a capacitor, a coupler, a microstrip, or an impedance matching unit.

4. The electronic device as claimed in claim 1, wherein one or ones of the passive elements are individually disposed thereon.

5. The electronic device as claimed in claim 1, the operating frequency of one or ones of the semiconductor chips is not less than 10 GHz.

6. The electronic device as claimed in claim 1, wherein the substrate defines a dissipation factor is not greater than 0.01.

7. The electronic device as claimed in claim 1, wherein the substrate is an insulating substrate.

8. The electronic device as claimed in claim 1, wherein the thin film layer includes a layer of thin metallic foil.

9. The electronic device as claimed in claim 1, wherein material(s) of one or ones of the semiconductor chips defines a band gap no less than 1 electron volt.

10. The electronic device as claimed in claim 1, wherein one or ones of the semiconductor chips are one or more epitaxial structures lift-off from an original wafer.

11. The electronic device as claimed in claim 10, wherein the original wafer is made of materials of Gallium Nitride (GaN), Silicon Carbide (SiC), Sapphire, Gallium Arsenide (GaAs), Silicon (Si), or Indium phosphide (InP).

12. The electronic device as claimed in claim 1, wherein one or ones of the semiconductor chips is compound semiconductors applied to radio frequency (RF) range.

13. The electronic device as claimed in claim 1, wherein the thin film layer further defines a feeding line.

14. The electronic device as claimed in claim 1, further including a first conductive layer formed on the second face of the substrate.

15. The electronic device as claimed in claim 14, wherein the conductive layer is a grounding or a common layer.

16. The electronic device as claimed in claim 14, wherein the first conductive layer is a patch antenna.

17. The electronic device as claimed in claim 16, the first conductive layer fully covers one or ones of the semiconductor chips in a projection direction perpendicular to the substrate.

18. The electronic device as claimed in claim 1, wherein one or ones of the semiconductor chips include(s) transistor(s), diode(s), or varactor(s), or any combination thereof.

19. An electronic apparatus comprising:
a board defining a third conductive layer;
one or ones of the electronic devices according to any of claims 1; and
a plural of second conductors electrically connecting the board and one or ones of the electronic device.

20. The electronic apparatus as claimed in claim 19, wherein the electronic device includes a first conductive layer formed on the second face of the substrate, and the conductive layer fully covers one or ones of the semiconductor chips in a projection direction perpendicular to the substrate.
